(19) United States
(12) Patent Application Publication
(10) Pub. No.: US 2010/0051088 A1
(43) Pub. Date: Mar. 4, 2010

(54) Photovoltaic solar concentrating power system

(76) Inventor: Alexander Levin, Binyamina (IL)

Correspondence Address: Levin Alexander, 5A Shvil Hachalav St., Binyamina, 30500, IL

(21) Appl. No.: 12/229,627

(22) Filed: Aug. 27, 2008

(51) Int. Cl. H01L 31/042

(52) U.S. Cl. 136/246

(57) ABSTRACT

The invention proposes a solar photovoltaic system, which includes concentrators of solar radiation of refractive type and an array of photovoltaic cells installed on a heat sink plate operating on the principle of a flat heat pipe.

### STATEMENT REGARDING FEDERALLY SPONSORED RESEARCH

Not applicable.

### BACKGROUND OF THE INVENTION

This invention relates to photovoltaic solar power systems and more specifically to solar photovoltaic systems, which include concentrators of solar radiation.

It is known that high cost of solar photovoltaic cells limits their wide application as renewable source of electrical energy. Usage of relatively cheap concentrators of solar radiation allows to diminish significantly the fraction of cost of a photovoltaic cell in the total cost of the photovoltaic solar power system and to achieve in such a way decrease of required investment per unit of generated power of this system.

This approach provides some advantages to solar concentrating photovoltaic systems as compared to common photovoltaic flat-plate systems. Concentrators ensure higher efficiency of converting solar radiation into electricity by photovoltaic solar cells. At the same time, significant reducing the size of solar cells gives possibility to apply more expensive solar cells with higher efficiency and improved stability of their output characteristics at high temperatures.

On the other hand, there are some technical problems to be solved in using concentrators of solar radiation. These problems relate to design of a suitable tracking mechanism and dissipation of heat released on the photovoltaic cells. There are some US patents, which are related to the area of solar photovoltaic systems with application of concentrators of solar radiation. For example, it is possible to mention U.S. Pat. Nos. 4,056,405, 4,361,717, 4,604,494, 4,971,633, 5,374,317.

Some US patents and patent applications should be considered at greater length.

US patent application No. 20080087321 describes an extensive photovoltaic array for generating electric power from concentrated solar radiation, formed of an extensive planar structural grid wherein a multitude of power generating modules are installed, said structural grid being positioned by a primary servomechanism to keep incident solar radiation perpendicular to the plane of the array at all times.

U.S. Pat. No. 6,700,055 describes a solar concentrator system, which includes a collector lens for collecting and at least partially focusing incident solar rays, a solar cell and a lens array positioned generally between the collector lens and the solar cell, the lens array directing the partially focused rays emerging from the collector lens onto the solar cell.

U.S. Pat. No. 7,190,531 teaches a Fresnel lens, which includes a substantially polygonal focusing portion adapted to focus solar radiation to an area having the same geometry as the focusing portion of the lens. Also a solar module includes the Fresnel collecting lens and a substantially polygonal photovoltaic cell. The photovoltaic cell is mounted at distance from the Fresnel collecting lens so that the size of the area substantially matches the size of the photovoltaic cell. Also a solar panel has multiple modules within a glazed building envelope system. The solar panel also includes an actuating mechanism within the glazed window envelope system. The actuating mechanism is operatively connected to the plurality of solar modules and is adapted to move the solar modules to track the sun.

US patent application No. 20070028960 describes an impinging liquid jet or jets cooling device and a method of designing an impinging liquid jet or jets cooling device is disclosed. The device is arranged such that drainage of a jet liquid is in a direction substantially perpendicular to a surface to be cooled. In some embodiments of this patent application the jets cooling device is used for cooling an array of photovoltaic cells.

US patent application No. 20070070531 describes a radiant energy concentrating or collimating system comprising an enclosure that shields its contents from environmental effects while allowing radiant energy to transmit through its top window; a plurality of energy concentrating or collimating assemblies, each on its own pivot mechanism and each comprising a plurality of optics, a support structure and an energy conversion device that is mounted on a heat dissipating structure; a drive mechanism controlled by a microprocessor to rotate the said energy concentrating or collimating assemblies on two orthogonal axes in unison so the assemblies are oriented towards desired direction at any given time.

US patent application No. 20050081908 describes a method of providing an apparatus and system comprising a complete smart solar electrical power generator system integrated into the form of a thin flat glass plate. The novel elements include: a micro-scale optical array, a new type of miniaturized photovoltaic cell, an inside-the-lens concentrator design, integral heat sinking and mechanical support, a sealed solid-state design with no air gaps and a new process for building it, combined reflective/refractive light concentration around the photovoltaic cell, variable solar concentration ratios, and a new integrated structure for interconnecting the system together.

US patent application No. 20030015233 describes a solar concentrator system, which includes a collector lens for collecting and at least partially focusing incident solar rays, a solar cell and a lens array positioned generally between the collector lens and the solar cell, the lens array directing the partially focused rays emerging from the collector lens onto the solar cell.

US patent application No. 20030140960 describes an energy converting system, which includes a cell array and a light concentrating unit directing concentrated light at the cell array, the cell array includes a plurality of cells, wherein the cells are coupled together according to the flux of the concentrated light which reaches each of the cells.

US patent application No. 20020121298 describes an apparatus for converting solar energy to thermal and electrical energy, which includes a photovoltaic grid for converting the concentrated solar energy into electrical energy mounted on a copper plate that provides even temperature dispersion across the plate and acts as a thermal radiator when the apparatus is used in the radiant cooling mode; and a plurality of interconnected heat transfer tubes located within the enclosure and disposed on the plane below the copper plate but conductively coupled to the copper plate for converting the solar energy to thermal energy in a fluid disposed within the heat transfer tubes. Fresnel lenses are affixed to the apparatus on mountings for concentrating the solar energy on to the photovoltaic grid and functioning as a passive solar tracker.

However, there is a necessity in technical solutions, which provide cheap and reliable constructions of solar photovoltaic power systems with application of concentrators of solar radiation.

### BRIEF SUMMARY OF THE INVENTION

The invention includes application of single curvature and compound-curvature concentrators.

These concentrators are designed as a glazing plate from a transparent polymer or glass with an array of single curvature or compound-curvature lenses. In a preferable version the lenses are designed as Fresnel lenses with single curvature (cylindrical Fresnel lenses) or compound curvature. A photovoltaic collector is provided in this case with axles and a mechanism for 1-axis (single curvature lenses) or 2-axis (compound curvature lenses) tracking after the sun motion.

In another preferable version there are two glazing plates with Fresnel lenses of single curvature, and the axes of these arrays of the Fresnel lenses are crossing at a right angle. At the same time, the planes of these glazing plates are in immediate vicinity; in such a way the combination of these glazing plates is focusing a significant fraction of the solar radiation (its non-diffusion fracture) in a form of separated spots, which are similar in form to rectangles.

The glazing plate(s) is installed on the upper aperture of rectangular housing, which is provided with lateral elements (axles etc.) for 2-axis tracking the entire photovoltaic collector after the sun motion.

The 2-axis tracking mechanism can be constructed on the base of a cardan suspension.

Photovoltaic cells are arranged in the focal points of the lenses on a rigid upper plate. This plate presents one side of a flat heat sink, which is functioning on the principle of a heat pipe and allows effectively spreading the heat, which is releasing on the photovoltaic cells.

The opposite side of the flat heat sink serves for dissipation of the heat in the environment.

It is achieved by convective heat transfer to the surroundings from the external surface of the opposite side and, additionally, by covering this external surface by a coating with high total emissivity.

The heat sink in the form of a flat heat pipe is constructed from two main plates, which are sealed at their edges. The upper plate, which serves for installation of the array of the photovoltaic cells, has high rigidity and the opposite lower plate is made from a thin flexible metal sheet. The internal surface of the upper plate is covered with a porous coating with open pores, which provides property of capillary soaking to this porous coating.

It is possible to construct the upper plate from two sheets: a lower metal sheet with the layer of porous capillary coating; this metal sheet has a small thickness; and an upper relatively thick sheet from a mineral material, for example, reinforced concrete or fiberglass. The lower and upper sheets are joined by gluing. The upper sheet is provided with openings arranged in such a manner, that the photovoltaic cells are installed in these openings on the lower metal sheet.

The internal surface of the opposite lower plate is covered also with such porous coating with the property of capillary soaking. In addition, this lower plate is provided with an array of dimples directed inwards; these dimples serve as spacers and, at the same time, they allow to transfer a liquid working medium to the porous coating of the upper plate; it is performed by an immediate contact of the top sections of the dimples with the porous coating of the upper plate.

The internal space of the flat heat pipe is filled with liquid and gaseous phases of a working medium. This working medium is chosen in such a way, that its working pressure (the pressure of the saturated vapors at a working temperature) is below the atmospheric pressure. It ensures forcing the lower opposite plate against the upper plate and the immediate contact of the top sections of the dimples with the porous coating of the upper plate.

In order to provide better contact of the dimples with the internal surface of the upper plate, the peripheral area of the lower plate can be designed as a bellows.

Such photovoltaic collector with refractive concentrators allow achieving further diminishment of proportion of solar cell cost in the general cost of the entire solar photovoltaic power system.

In another version, there is a sheet-wise capillary wick placed between the upper and lower plates; this sheet-wise capillary wick serves as an artery wick, which ensures collecting condensate of the working medium from the internal surface of the lower plate and its transfer to the capillary porous coating of the upper plate.

It gives possibility to apply an array of corrugations on the lower plate in place of the dimples; these corrugations are directed inwards and decrease in dimension to zero at the opposite ends. In this case, the capillary coating of the lower plate can be obviated.

There are some advantages of the proposed solar power system:

1. High reliability;
2. Low cost of 1 kW of electrical power generated by the system.
3. Low O&M expenditures.

### BRIEF DESCRIPTION OF THE SEVERAL VIEWS OF THE DRAWINGS

FIG. 1a and FIG. 1b show a transversal cross-section of a photovoltaic collector with a glazing plate comprising an array of Fresnel lenses (without a tracking mechanism), when dimples of a lower plate of a flat heat pipe are not in contact with an upper plate (FIG. 1a), and when these dimples are in contact with the upper plate (FIG. 1b).

FIG. 2 shows a transversal cross-section of a photovoltaic collector with two parallel glazing plates, with Fresnel lenses of single curvature and projections of the axes of these arrays of the Fresnel lenses are crossing at a right angle.

FIG. 3 shows a top view of the lower plate.

FIG. 4 shows a transversal cross-section of a flat heat pipe with photovoltaic cells installed on its upper outer surface.

FIG. 5 shows a top view of the upper plate in the case of application of a glazing plate with compound curvature Fresnel lenses (or two parallel glazing plates with single curvature Fresnel lenses).

FIG. 6 shows a top view of the upper plate in the case of application of a glazing plate with single curvature Fresnel lenses.

FIG. 7 shows a top view of the lower plate provided with an array of parallel corrugations, which are directed inwards and decrease in dimension to zero in the vicinity of their edges.

FIG. 8 shows a top view of the lower plate provided with an array of parallel corrugations.

FIG. 9 shows a transversal cross-section of a flat heat pipe with photovoltaic cells installed on its upper outer surface and a flexible flat wick, which is situated between the upper and lower plates.

### DETAILED DESCRIPTION OF THE INVENTION

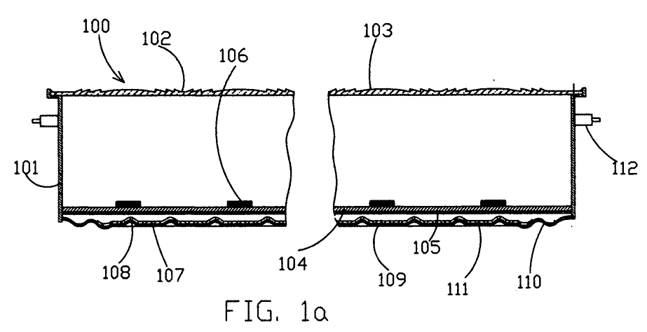

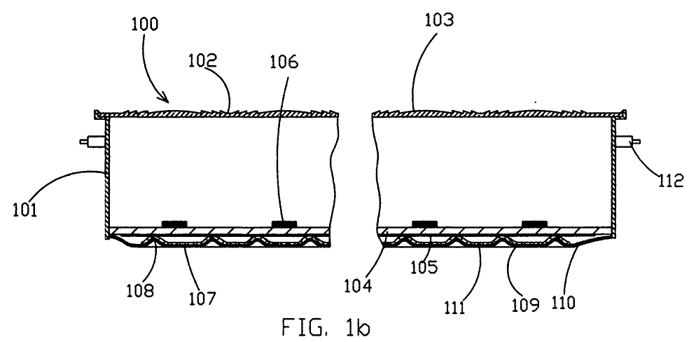

FIG. 1a and FIG. 1b show a transversal cross-section of a photovoltaic collector with a glazing plate comprising an array of Fresnel lenses (without a tracking mechanism), when dimples of a lower plate of a flat heat pipe are not in contact with an upper plate (FIG. 1a), and when these dimples are in contact with the upper plate (FIG. 1b).

This photovoltaic collector 100 comprises frame 101 with axles 112 to be joined with a tracking mechanism, a glazing plate 102 and an array of single curvature Fresnel lenses 103 in this glazing plate 102.

The upper plate 104 of high rigidity is installed in frame 101 and provided with a lower layer of a capillary coating 105. This upper plate 104 serves for installation of an array of photovoltaic cells 106, which are located at the focusing points of the Fresnel lenses 103.

There is a lower plate 107, which is sealed with the upper plate 104 at its edges. The lower plate 107 is provided with an array of dimples 108 directed inwards and the upper surface of this lower plate 107 is covered with a porous capillary coating 111. The bottom surface of the lower plate 107 is covered with coating 109 with high total emissivity.

The peripheral region of the lower plate is formed as bellows 110; this allows achieving significant displacement of the most area of the lower plate 107 inwards, when the pressure of a working medium in the internal space between the upper and lower plates 104 and 107 is under atmospheric pressure. It is achieved by filling the internal space between the upper and lower plates 104 and 107 with the working medium in liquid and vaporous forms, when the pressure of the working medium vapors at an operating temperature is lower than the atmospheric pressure.

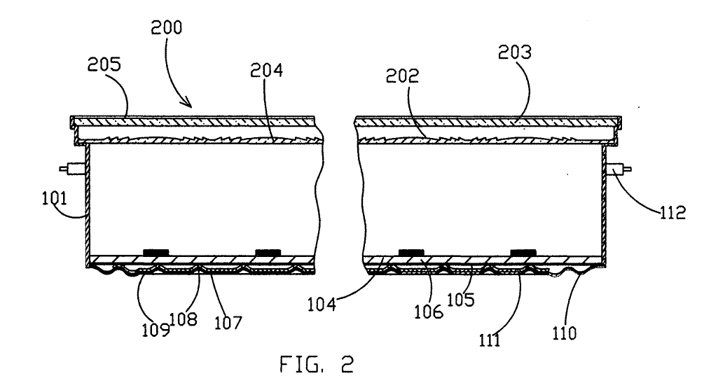

FIG. 2 shows a transversal cross-section of a photovoltaic collector 200 with two parallel glazing plates 202 and 203 with Fresnel lenses 204 and 205 of single curvature and projections of the axes of these arrays of the Fresnel lenses are crossing at a right angle. At the same time, the planes of these glazing plates are situated in immediate vicinity.

Other elements of the photovoltaic collector 200 are signed as in FIG. 1a and FIG. 1b.

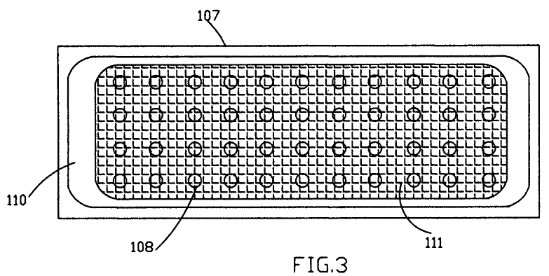

FIG. 3 shows a top view of the lower plate.

It shows the lower plate 107 with dimples 108, a peripheral bellows 110 and the inner capillary coating 111.

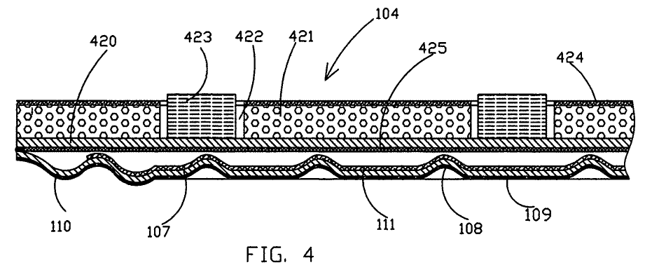

FIG. 4 shows a cross-section of a flat heat pipe with photovoltaic cells installed on its upper outer surface.

It comprises the upper plate 104 and the lower plate 107. The upper plate consist of a metal sheet 420, a rigid sheet 421 from a mineral material, which is glued with the metal sheet 420 and provided with openings 422; an array of photovoltaic cells 423 is installed on the metal sheet 420 in openings 422.

The metal sheet 420 is provided with a lower layer of a capillary coating 425.

In addition, the upper surface of the rigid sheet 421 is covered with coating 424 with high total emissivity.

The lower plate 107, which is sealed with the upper plate 104 at its edges, is provided with an array of dimples 108 directed inwards and with a peripheral bellows 110.

The bottom surface of the lower plate 107 is covered with coating 109 with high total emissivity. The upper surface of this lower plate 107 is covered with a porous capillary coating 111.

The inner space between the upper and lower plates 104 and 107 is filled with a working medium in liquid and vaporous forms, when the pressure of the working medium vapors in the range of operating temperatures is lower than the atmospheric pressure.

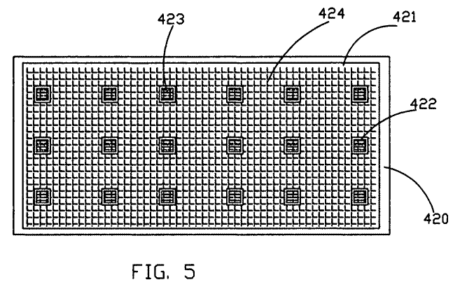

FIG. 5 shows a top view of the upper plate in the case of application of a glazing plate with compound curvature Fresnel lenses (or two parallel glazing plates with single curvature Fresnel lenses).

It comprises a mineral rigid sheet 421, openings 422 and photovoltaic cells 423.

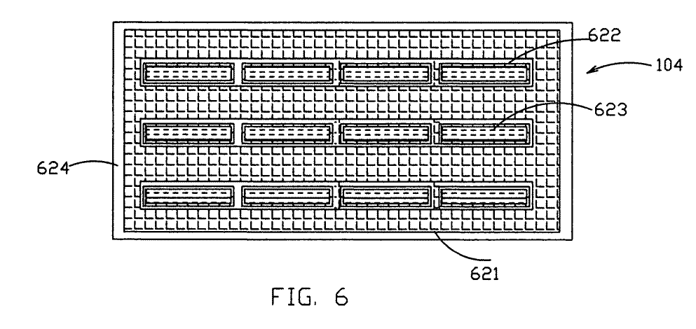

FIG. 6 shows a top view of the upper plate 104 in the case of application of a glazing plate with single curvature Fresnel lenses. It comprises a mineral rigid sheet 621, openings 622 and photovoltaic cells 623, which are installed in these openings on a metal sheet 624.

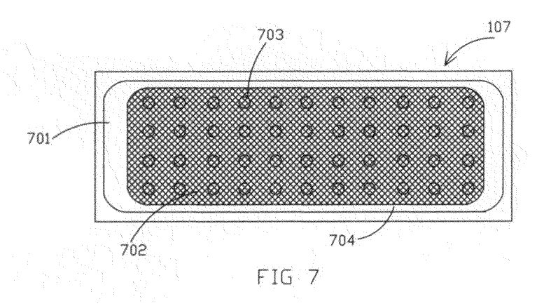

FIG. 7 shows a top view of the lower plate 107 provided with an array of dimples 703, which are directed inwards.

It shows a tin metal sheet 704 with dimples 703, a peripheral bellows 701 and the inner capillary coating 702.

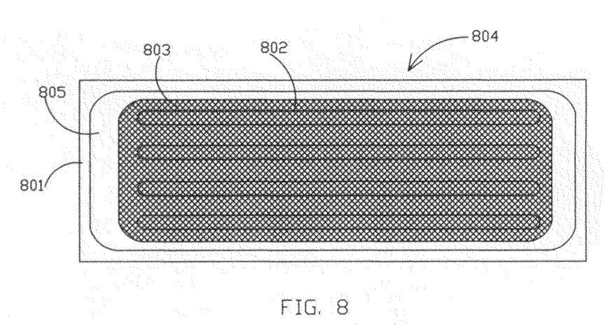

FIG. 8 shows a top view of a lower plate 804 provided with an array of parallel corrugations 802, which are directed inwards and decrease in dimension to zero in the vicinity of their edges.

It shows the lower plate 804, which comprising a thin metal sheet 801 with corrugations 802, a peripheral bellows 805 and the inner capillary coating 803.

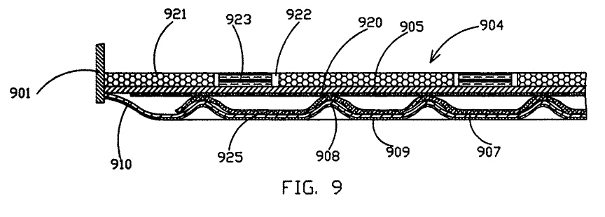

FIG. 9 shows a section of a flat heat pipe with photovoltaic cells installed on its upper outer surface and a flexible flat wick, which is situated between the upper and lower plates.

It comprises the upper plate 904 and the lower plate 907. The upper plate consist of a metal sheet 920, a rigid sheet 921 from a mineral material, which is glued with the metal sheet 920 and provided with openings 922; an array of photovoltaic cells 923 is installed on the metal sheet 920 in openings 922. The metal sheet 920 is provided with a lower layer of a capillary coating 905.

The lower plate 907, which is sealed with the metal sheet 920 at titsedges, is provided with an array of dimples 908 directed inwards and a peripheral bellows 910.

The bottom surface of the lower plate 907 is covered with coating 909 with high total emissivity.

The inner space between the metal sheet 920 and the lower plate 907 is filled with a working medium in liquid and vaporous forms, when the pressure of the working medium vapors at an operating temperature is lower than the atmospheric pressure.

In addition, there is a flat flexible wick 925, which is positioned between the metal sheet 920 and the lower plate 907 and serves for soaking the condensate from the internal surface of this lower plate 907 and its transfer onto the capillary coating 905.

I claim:

1. A photovoltaic collector consisting of:
a frame with axles serving for 1-axis tracking said photovoltaic collector after the sun motion;
a glazing of said frame; said glazing comprises an array of single-curvature lenses;
a flat heat sink, which is functioning on the principle of a heat pipe and is installed in said frame; said flat heat sink comprises an upper and lower plates, which are sealed at their edges; said lower plate is provided with an array of dimples directed inwards and the inner surfaces of said upper and lower plates are covered with a capillary coatings; the internal space between said upper and lower plates is filled with a liquid medium and its vapors.
an array of photovoltaic cells, which are installed on said upper plate of said flat heat sink in the focal lines of said single-curvature lenses.

2. A photovoltaic collector as claimed in claim 1, wherein the pressure of vapors of said liquid medium in the range of working temperatures of said photovoltaic collector is below the atmospheric pressure.

3. A photovoltaic collector as claimed in claim 1, wherein said lower plate is a thin metal sheet with high flexibility.

4. A photovoltaic collector as claimed in claim 3, wherein said thin metal sheet is provided with peripheral bellows.

5. A photovoltaic collector as claimed in claim 1, wherein the external side of the lower plate is covered with a coating with high total emissivity.

6. A photovoltaic collector as claimed in claim 1, wherein the single curvature lenses are formed as single curvature Fresnel lenses.

7. A photovoltaic collector as claimed in claim 1, wherein the upper plate has high rigidity.

8. A photovoltaic collector as claimed in claim 1, wherein the outer side of the upper plate, which is not occupied by the photovoltaic cells, is covered with a coating with high total emissivity.

9. A photovoltaic collector as claimed in claim 7, wherein the upper plate comprises a thin metal sheet with a capillary coating on its internal side and a sheet from a mineral material, which is positioned from above and glued with said thin metal sheet; said mineral sheet is provided with openings for installation the photovoltaic cells on said thin metal sheet.

10. A photovoltaic collector as claimed in claim 9, wherein the mineral material is glass.

11. A photovoltaic collector as claimed in claim 9, wherein the mineral material is asbestos cement.

12. A photovoltaic collector as claimed in claim 1, wherein the lower plate is provided with an array of corrugations; said corrugations are directed inwards and decrease in dimension to zero in the vicinity of their edges.

13. A photovoltaic collector as claimed in claim 1, wherein there is a flat flexible wick, which is positioned between the upper and lower plates and serves for soaking the condensate from the internal surface of said lower plate and its transfer onto the capillary coating of said upper plate.

14. A photovoltaic collector as claimed in claim 1, wherein there are two glazing plates with Fresnel lenses of single curvature, and projections of the axes of the arrays of said Fresnel lenses are crossing at a right angle; at the same time, the planes of said glazing plates are positioned in immediate vicinity; the photovoltaic cells are installed in spots formed by combined concentration of solar radiation obtained by said Fresnel lenses of said two glazing plates, and the frame with axles serves for 2-axis tracking said photovoltaic collector after the sun motion.

15. A photovoltaic collector as claimed in claim 1, wherein the frame with axles serves for 2-axis tracking said photovoltaic collector after the sun motion; the glazing of said frame comprises an array of compound curvature lenses, and the photovoltaic cells are installed on the upper plate in focal points of said compound curvature lenses of said glazing plate, and the frame with the axles serves as elements of 2-axis tracking mechanism of said photovoltaic collector for tracking after the sun motion.

16. A photovoltaic collector as claimed in claim 16, wherein the compound curvature lenses are formed as Fresnel compound curvature lenses.

17. A photovoltaic collector as claimed in claim 15, wherein the 2-axis tracking mechanism is constructed on the base of a cardan suspension.

18. A photovoltaic collector as claimed in claim 15, wherein the 2-axis tracking is constructed on the base of a cardan suspension.
